(19) United States
(12) Patent Application Publication
(10) Pub. No.: US 2025/0331215 A1
(43) Pub. Date: Oct. 23, 2025

(54) GATE METALLIZATION DESIGN FOR e-MODE GaN HEMTS

(71) Applicant: Indian Institute of Science, Bangalore (IN)

(72) Inventors: Rasik Rashid Malik, Bangalore (IN); Mayank Shrivastava, Bangalore (IN)

(21) Appl. No.: 19/187,575

(22) Filed: Apr. 23, 2025

(30) Foreign Application Priority Data
Apr. 23, 2024 (IN) 202441032159

(51) Int. Cl. H10D 30/47; H10D 30/01; H10D 62/10; H10D 62/824; H10D 64/62; H10D 64/64; H10D 64/66; H10D 64/68

(52) U.S. Cl. CPC H10D 30/475; H10D 30/015; H10D 30/472; H10D 62/102; H10D 62/824; H10D 64/62; H10D 64/64; H10D 64/665; H10D 64/667; H10D 64/693

(57) ABSTRACT

A gate (100) for a HEMT (10) to prevent leakage and improve gate stability is configured between the source structure (102-A) and the drain structure (102-B). The gate structure (124) includes a p-type capping layer (108), and a first layer (104) configured with the p-type capping layer (108) to form a Schottky contact with the p-type capping layer (108). The first layer (104) in the gate structure comprises any or the combination of low work function metal or metal alloy such as scandium (Sc) or the tantalum (Ta) or Titanium metal or Titanium Nitride (TiN) or Tantalum Nitride (TaN), with or without gold (Au) to make the Schottky contact with the p-type capping layer (108) in order to suppress gate leakage, improve gate breakdown, and stability to prevent leakage of electric current from the gate structure (124) to the heterojunction structure.

### TECHNICAL FIELD

The present disclosure relates in general to material engineering and fabrication of gate terminals for high electron mobility transistors. M ore particularly, the present disclosure relates to a gate for a high electron mobility transistor aiming to prevent gate leakage, enhance gate stability, and increase breakdown voltage.

### BACKGROUND

The information in this section merely provides background information related to the present disclosure and may not constitute prior art(s) for the present disclosure.

Gallium Nitride High Electron Mobility Transistors (GaN HEMTs) have emerged as essential components in high-frequency and high-power electronic devices due to their characteristics, such as high electron mobility, high breakdown voltage, and low on-resistance. However, the effective implementation of these devices relies on the quality of the gate contact, which significantly impacts device performance and reliability.

Traditionally, Schottky gate contacts have been widely used in GaN HEMTs due to their simplicity and compatibility with high power operation. However, the choice of materials for Schottky gate contacts is crucial to achieve the desired performance from the device. In particular, for p-GaN gate AlGaN/GaN HEMTs, finding suitable gate metallization materials poses a challenge.

There is, therefore, a requirement in the art to overcome the above-mentioned problem of enhancing the efficiency of transistors by providing a simple, compact, and efficient system to prevent gate leakage, enhance gate stability, and improve gate voltage swing in high electron mobility transistors.

### OBJECTS OF THE PRESENT DISCLOSURE

Some of the objects of the present disclosure, which at least one embodiment herein satisfies are listed herein below.

It is an object of the present disclosure to provide a High Electron Mobility Transistor (HEMT) device including a gate structure and a source drain structure. The gate structure includes a p-type capping layer, and a first layer configured with the p-type capping layer to form a Schottky contact with the p-type capping layer. The source drain structure includes a multilayer stack with any or a combination of a contact layer, an overlayer, a barrier contact layer, and a cap layer, and the contact layer makes ohmic contact with a heterojunction structure.

It is an object of the present disclosure to provide a High Electron Mobility Transistor (HEMT) device where the first layer includes any or the combination of a low work function (<4.6 eV) metal or metal alloy such as scandium (Sc˜3.5 eV), the tantalum (Ta˜4.2 eV), Ti (˜4.33 eV), Titanium Nitride (TiN) or Tantalum Nitride (TaN), with or without gold (Au) to make the Schottky contact with the p-type capping layer in order to suppress gate leakage, improve gate breakdown, and stability to prevent leakage of electric current from the gate structure to the heterojunction structure.

It is an object of the present disclosure to provide a High Electron Mobility Transistor (HEMT) device where the contact layer includes any or a combination of a low work function metal or metal alloy such as scandium (Sc) or the tantalum (Ta) or Titanium metal or Titanium Nitride (TiN) or Tantalum Nitride (TaN), with or without Silicon (Si) doping to form the ohmic contact with the heterojunction structure.

It is an object of the present disclosure to provide a High Electron Mobility Transistor (HEMT) device where the p-type capping layer is disposed on a barrier layer, and the barrier layer is configured with the heterojunction structure formed of any or a combination of Aluminium and Gallium Nitride (AlGaN), Aluminium Nitride (AlN), Indium Nitride (InN), and their corresponding alloys.

It is an object of the present disclosure to provide a High Electron Mobility Transistor (HEMT) device where the p-type capping layer (106) is formed of any or a combination of p-type Aluminum Titanium Oxide (p-AlTiO), p-type Nickel Oxide (p-NiOx), a p-type Gallium Nitride (p-GaN) in a crystalline form or an amorphous form.

It is an object of the present disclosure to provide a High Electron Mobility Transistor (HEMT) device where a layer (108) with any or a combination of Silicon Dioxide (SiO₂), Silicon Nitride (SiN), and Aluminium Oxide (AlOx) is disposed on the first layer (104), acting as a hard mask for removal of the first layer (104) among non-gated regions.

It is an object of the present disclosure to provide a High Electron Mobility Transistor (HEMT) device where a dielectric medium such as SiOx, SiNx, Al₂O₃, or any or a combination of semiconductors comprising AlN, GaON, GaOx separates the scandium (Sc) or the tantalum (Ta) metal and the p-GaN structure.

### SUMMARY

In an aspect, the present disclosure relates to a High Electron Mobility Transistor (HEMT) device. The HEMT device include a gate structure and a source drain structure, where the gate structure includes a p-type capping layer, and a first layer configured with the p-type capping layer to form a Schottky contact with the p-type capping layer. The source drain structure includes a multilayer stack with any or a combination of a contact layer, an overlayer, a barrier contact layer, and a cap layer, and wherein the contact layer makes ohmic contact with a heterojunction structure.

In an embodiment, the first layer may include any or the combination of a low work function (<4.6 eV) metal or metal alloy such as scandium (Sc˜3.5 eV), the tantalum (Ta˜4.2 eV), Ti (˜4.33 eV), Titanium Nitride (TiN) or Tantalum Nitride (TaN), with or without gold (Au) to make the Schottky contact with the p-type capping layer (108) in order to suppress gate leakage, improve gate breakdown, and stability to prevent leakage of electric current from the gate structure (124) to the heterojunction structure.

In an embodiment, the contact layer may include any or a combination of a low work function metal or metal alloy such as scandium (Sc) or the tantalum (Ta) or Titanium metal or Titanium Nitride (TiN) or Tantalum Nitride (TaN), with or without Silicon (Si) doping to form the ohmic contact with the heterojunction structure.

In an embodiment, the p-type capping layer may be disposed on a barrier layer, and where the barrier layer may be configured with the heterojunction structure formed of any or a combination of Aluminium and Gallium Nitride (AlGaN), Aluminium Nitride (AlN), Indium Nitride (InN), and their corresponding alloys.

In an embodiment, the p-type capping layer may be formed of any or a combination of p-type Aluminum Titanium Oxide (p-AlTiO), p-type Nickel Oxide (p-NiOx), a p-type Gallium Nitride (p-GaN) in a crystalline form or an amorphous form.

In an embodiment, a layer with any or a combination of Silicon Dioxide (SiO₂), Silicon Nitride (SiN), and Aluminium Oxide (AlOx) may be disposed on the first layer, acting as a hard mask for removal of the first layer among non-gated regions.

In an aspect, a semiconductor device includes any or a combination of a low work function metal or metal alloy such as scandium (Sc) or the tantalum (Ta) or Titanium metal or Titanium Nitride (TiN) or Tantalum Nitride (TaN), to form a Schottky contact with the p-capping layer and make an ohmic contact with a n-GaN/n-Semiconductor/n-dielectric layer or a Schottky contact with a p-GaN/p-Semiconductor/p-dielectric structure.

In an embodiment, a dielectric medium such as SiOx, SiNx, Al₂O₃, or any or a combination of semiconductors comprising AlN, GaON, GaOx may separate the low work function metal or metal alloy such as scandium (Sc) or the tantalum (Ta) or Titanium metal or Titanium Nitride (TiN) or Tantalum Nitride (TaN), and the p-capping layer in the gate structure.

In an aspect, the present disclosure relates to a method fabricating a HEMT device. The method includes depositing, a a gate structure with any or combination of a low work function metal or metal alloy such as scandium (Sc) or the tantalum (Ta) or Titanium metal or Titanium Nitride (TiN) or Tantalum Nitride (TaN), and a hard mask with any or combination of a SiOx layer, SiNx layer, an AlOx layer, an AlN layer, a Cr layer, an Au layer, and a Ni layer. The method includes etching a p-GaN layer with the gate structure. The method includes etching, a MESA layer with the gate structure for isolation of the HEM T device. The method includes forming, an ohmic contact with a source and drain structure of the HEMT device using a metal stack. The method includes depositing, for passivation using any or a combination of a SiOx layer, a SiNx layer, an AlOx layer, a TiOx layer, and an AlN layer, in a single layer or a multilayer stacking of any stoichiometry or stress. The method includes performing, passivation opening and metal thickening of the gate structure. The method includes performing, post metallization annealing of the gate structure.

In an embodiment, the method may include depositing a first layer with any or the combination of the scandium (Sc) or the tantalum (Ta) metal with or without gold (Au) to make the Schottky contact with the p-type capping layer to suppress gate leakage, improve gate breakdown, and stability to prevent leakage of electric current from the gate structure to a heterojunction structure configured with the HEMT device.

In an embodiment, the method may include disposing, the p-type capping layer on a barrier layer, where the barrier layer may be configured with the heterojunction structure formed of any or a combination of Aluminium and Gallium Nitride (AlGaN), Aluminium Nitride (AlN), Indium Nitride (InN), and their corresponding alloys. The method may include disposing, a layer with any or a combination of Silicon Dioxide (SiO2), Silicon Nitride (SiN), and Aluminium Oxide (AlOx) on the first layer, acting as a hard mask for removal of the first layer among non-gated regions.

Various objects, features, aspects, and advantages of the inventive subject matter will become more apparent from the following detailed description of preferred embodiments, along with the accompanying drawing figures in which like numerals represent like components.

### BRIEF DESCRIPTION OF FIGURES

The accompanying drawings are included to provide a further understanding of the present disclosure and are incorporated in and constitute a part of this specification. The drawings illustrate exemplary embodiments of the present disclosure and, together with the description, serve to explain the principles of the present disclosure.

FIGS. 1A to 1B illustrates a schematic cross-sectional view of the gate for a high electron mobility transistor (HEMT) in accordance with an embodiment of the present disclosure.

FIG. 1C illustrates a flow chart of the fabrication process of the proposed gate using a scandium (Sc)/tantalum (Ta) based gate stack, in accordance with an embodiment of the present disclosure.

FIGS. 2A to 2D illustrate a graphical representation comparing the gate leakage characteristics of the proposed gate, in accordance with an embodiment of the present disclosure.

FIG. 3A illustrate a graphical representation comparing the transfer characteristics of a HEM T with the proposed gate based on Sc/Au or Ta/Au and TiN, in accordance with an embodiment of the present disclosure.

FIG. 3B illustrates a graphical representation comparing the threshold voltage (VTH) drifts with HEM Ts employing proposed gate-based on Sc/Au or Ta/Au with and without Ni, in accordance with an embodiment of the present disclosure.

FIG. 4A illustrates a schematic representation of a stress test implemented on the proposed gate, in accordance with an embodiment of the present disclosure.

FIGS. 4B illustrates a graphical representation of the performance of the TiN-based gate stack during the stress test, in accordance with an embodiment of the present disclosure.

FIG. 4C illustrates a graphical representation of the performance of the proposed gate during the stress test, in accordance with an embodiment of the present disclosure.

FIG. 5 illustrates a graphical representation of comparison of threshold voltage stability between the proposed gate with Sc/Au or Ta/Au, a TiN based gate, and the gate Sc/Au or Ta/Au and TiN, in accordance with an embodiment of the present disclosure.

FIG. 6 illustrates a graphical representation of an energy band diagram of the proposed gate (Sc˜3.5 eV, Ta˜4.2 eV) metal stacking as compared to conventional (TiN˜4.6 eV) gate stack with the p-GaN structure, in accordance with an embodiment of the present disclosure.

FIG. 7 illustrates a graphical representation of the TCAD based gate leakage characteristics of ultra-low work function (Sc˜3.5 eV, Ta˜4.2 eV) metal stacking of the proposed gate as compared to conventional (TiN˜4.6 eV) gate stack, in accordance with an embodiment of the present disclosure.

FIG. 8 illustrates a graphical representation of comparison of gate breakdown behaviour between the proposed gate and the TiN based gate, in accordance with an embodiment of the present disclosure.

FIG. 9 illustrates a graphical representation of temperature dependent breakdown variation of the TiN based gate and the proposed gate, in accordance with an embodiment of the present disclosure.

FIG. 10 illustrates a graphical representation of variation of gate breakdown behaviour, between the proposed gate and the TiN based gate, in accordance with an embodiment of the present disclosure.

FIG. 11 illustrates a graphical representation of temperature dependent breakdown behaviour of inclusion of Ni in theproposed gate with the Sc/Au or Ta/, in accordance with an embodiment of the present disclosure.

FIG. 12 illustrates a graphical representation of variation in maximum gate breakdown voltage of the proposed gate with state of the art, in accordance with an embodiment of the present disclosure.

FIGS. 12A-12D illustrates Transmission Electron Microscopy schematic representations of the proposed gate, in accordance with an embodiment of the present disclosure.

FIGS. 13A-13D illustrates schematic representations of the proposed gate with various layers, in accordance with an embodiment of the present disclosure.

Skilled artisans will appreciate that elements in the drawings are illustrated for simplicity and have not necessarily been drawn to scale. For example, the dimensions of some elements in the drawings may be exaggerated relative to other elements to help to improve understanding of embodiments of the present disclosure.

### DETAILED DESCRIPTION

The one or more shortcomings of the prior art are overcome by the system as disclosed, and additional advantages are provided through the provision of the system as disclosed in the present disclosure. Additional features and advantages are realized through the techniques of the present disclosure. Other embodiments and aspects of the disclosure are described in detail herein and are considered a part of the disclosure.

Spatially relative terms, such as “under”, “below”, “lower”, “over”, “upper”, “top”, “bottom” and the like, may be used herein for ease of description to describe one element or feature's relationship to another element(s) or feature(s) as illustrated in the FIGs. It will be understood that the spatially relative terms are intended to encompass different orientations of the device in use or operation in addition to the orientation depicted in the FIGs. For example, if the device in the figures is turned over, elements described as “under”, or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly.

Herein, the terms “attached”, “connected”, “interconnected”, “contacting”, “mounted”, “coupled” and the like can mean either direct or indirect attachment or contact between elements, unless stated otherwise.

Well-known functions or constructions may not be described in detail for brevity and/or clarity. As used herein the expression “and/or” includes any and all combinations of one or more of the associated listed items.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises”, “comprising”, “includes” and/or “including” when used in this specification, specify the presence of stated features, operations, elements, and/or components, but do not preclude the presence or addition of one or more other features, operations, elements, components, and/or groups thereof.

The present embodiment relates in general to material engineering and fabrication of gate terminals for high electron mobility transistors. More particularly, the present embodiment relates to a gate for a high electron mobility transistor preventing gate leakage.

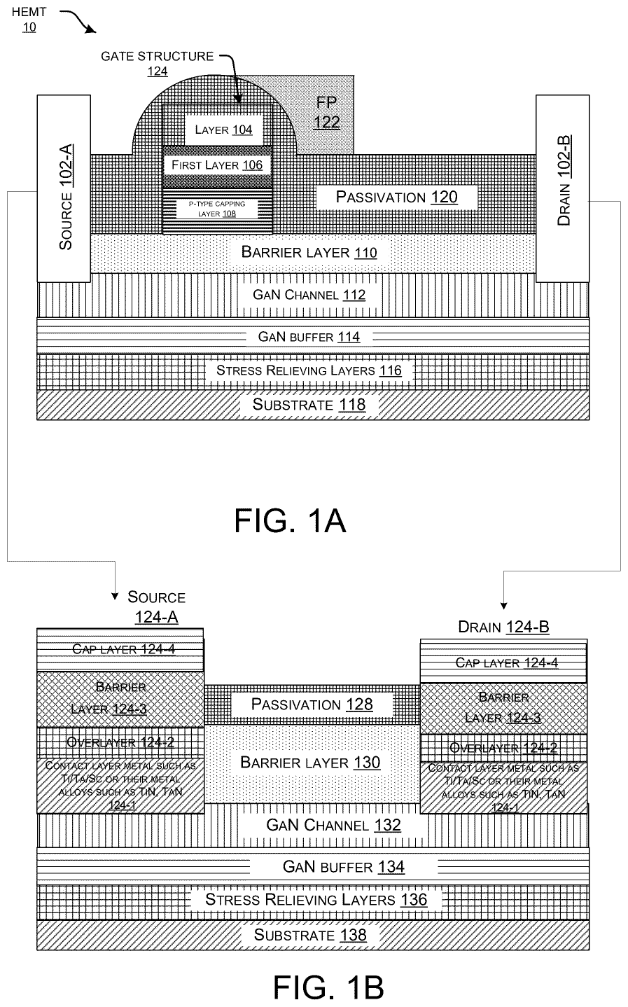

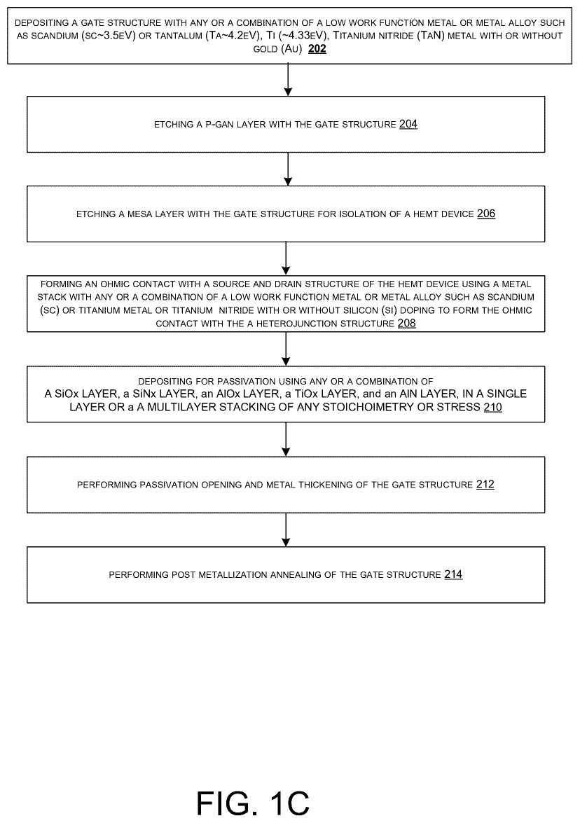

According to an aspect, a High Electron Mobility Transistor (HEMT) device (10) may include a gate structure 124 and a source drain structure (102-A, 102-B) where the gate structure 124 may include a p-type capping layer 106 and a first layer 106 configured with the p-type capping layer to form a Schottky contact with the p-type capping layer. The source drain structure (124-A, 124-B as shown in FIG. 1B) may include a multilayer stack (as shown in FIG. 1B) with any or a combination of a contact layer, an overlayer, a barrier contact layer, and a cap layer and where the contact layer 124-1 makes ohmic contact with a heterojunction structure (as shown in FIG. 1B), where the heterojunction structure may include a GaN channel 112, a GaN buffer 114, one or more stress relieving layers 116, and a substrate 118. Further, the contact layer 124-1 may include a contact layer metal such as Ti/Ta/Sc or their metal alloys such as TiN, TaN.

In an embodiment, the first layer 106 may include any or a combination of the scandium (Sc) or the tantalum (Ta) metal with or without gold (Au) to make the Schottky contact with the p-type capping layer in order to suppress gate leakage, improve gate breakdown, and stability to prevent leakage of electric current from the gate structure to the heterojunction structure (GaN channel 112, the GaN buffer 114, one or more stress relieving layers 116, and the substrate 116). Further, a passivation layer 120 and a barrier layer 110 may be configured between the source structure 102-A and the drain structure 102-B.

In an embodiment, the contact layer (124-1) may include any or a combination of scandium (Sc) or the tantalum (Ta) metal with or without Silicon (Si) doping to form the ohmic contact with the heterojunction structure.

In an embodiment, the p-type capping layer 108 may be disposed on a barrier layer 110, and the barrier layer 110 may be configured with the heterojunction structure formed with any or a combination of Aluminium and Gallium Nitride (AlGaN), Aluminium Nitride (AlN), Indium Nitride (InN), and their corresponding alloys.

In an embodiment, the p-type capping layer 108 may be formed with any or a combination of p-type Aluminum Titanium Oxide (p-AlTiO), p-type Nickel Oxide (p-NiOx), a p-type Gallium Nitride (p-GaN) in a crystalline form or an amorphous form.

In an embodiment, a layer 104 with any or a combination of Silicon Dioxide (SiO₂), Silicon Nitride (SiN), and Aluminium Oxide (AlOx) may be disposed on the first layer 106, acting as a hard mask for removal of the first layer 106 among non-gated regions.

As illustrated in FIG.1B, in an embodiment, the heterojunction structure (of FIG. 1B) may include the (a GaN channel 132, a GaN buffer 134, one or more stress relieving layers 126, and a substrate 138). Further, a passivation layer 128 and a barrier layer 130 may be configured between the source structure 124 and the drain structure 126.

In another aspect, a semiconductor device may include any or a combination of scandium (Sc) or tantalum (Ta) metal to form a part of a gate structure and make an ohmic contact with a n-GaN/n-Semiconductor/n-Oxide layer or a Schottky contact with a p-GaN/p-Semiconductor/p-dielectric structure.

In an embodiment, a dielectric medium such as SiOx, SiNx, Al₂O₃, or any or a combination of semiconductors including AlN, GaON, GaOx may separate the scandium (Sc) or the tantalum (Ta) metal and the p-GaN structure.

In an embodiment, the gate structure 124 can be heated at a temperature of 250 degrees Celsius for one hour in a vacuum environment during fabrication.

In an embodiment, the scandium (Sc) or tantalum (Ta) based metallization can facilitate the fabrication of ultra-low work function (Sc˜3.5 eV, Ta˜ 4.2 eV) metal stacking of gate structure 124, enabling effective (high barrier) Schottky contacts with p-GaN or p-type oxide.

In an embodiment, the multilayer stacking of Scandium (Sc) or tantalum (Ta) with nickel (Ni) and/or gold (Au) can allow higher values (3.5-5.15 eV) for adjustment of the work function. Sc/Ni or Ta/Ni stacking may lead towards high work function Schottky contacts with p-type materials. The interface quality of the p-type GaN can depend on a multilayer stacking of scandium (Sc) or tantalum (Ta) with other metals whereas the multilayer stacking of scandium (Sc) or tantalum (Ta) with gold (Au) can have better interface quality.

Referring to FIG. 1C, at step 202, the method may include depositing, a gate structure 124 with any or combination of a low work function metal or metal alloy such as scandium (Sc) or the tantalum (Ta) or Titanium metal or Titanium Nitride (TiN) or Tantalum Nitride (TaN), and a hard mask with any or combination of a SiOx layer, SiNx layer, an AlOx layer, an AlN layer, a Cr layer, an Au layer, and a Ni layer. At step 204, the method may include etching a p-GaN layer 108 with the gate structure 124. At step 206, the method may include etching, a MESA layer with the gate structure 124 for isolation of the HEMT device 10. At step 208, the method may include forming, an ohmic contact with a source and drain structure (102-A, 102-B) of the HEMT device 10 using a metal stack with any or combination of a low work function metal or metal alloy such as scandium (Sc) or titanium nitride (TiN) with or without silicon (Si) doping to form the ohmic contact with a heterojunction structure. At step 210, the method may include depositing, for passivation using any or a combination of a SiOx layer, a SiNx layer, an AlOx layer, a TiOx layer, and an AlN layer, in a single layer or a multilayer stacking of any stoichiometry or stress. At step 212, the method may include performing, passivation opening and metal thickening of the gate structure 124. At step 214, the method may include performing, post metallization annealing of the gate structure 124.

In an embodiment, the scandium (Sc) or Tantalum (Ta) metal may have a low work function of Sc˜3.5 eV and Ta˜4.2 eV and a melting point of Sc ˜1,541 and Ta˜3,017 degrees Celsius which can prevent the leakage of current when combined with gold (Au) metal such that the stacked along with gold (Au) in the top layer 104 of the gate 100 and can mitigate the gate leakage between the source terminal 102-A and the drain terminal 102-B of the GaN HEMT 10. In addition, the proposed gate 100 (hereinafter interchangeably referred to as “gate stack 100”) may significantly suppress gate leakage variability, indicating an enhanced p-GaN interface.

In an experiment, the layer 104 of the proposed gate structure 124 can be a combined Sc and Ni where the results may not be promising for the Sc/Ni/Au metal stack. Furthermore, when the metals scandium (Sc) or tantalum (Ta) and gold (Au) metal stack are combined, the results showed a significantly lower gate leakage from the gate structure 124 to the HEMT 10. Moreover, the proposed gate structure 100 when compared to the titanium nitride (TiN) based gate metal stack, the scandium (Sc) or tantalum (Ta) and gold (Au) gate stack can exhibit minimal gate leakage and improved threshold voltage stability.

Furthermore, the layer 104 which can be the scandium (Sc) or tantalum and gold (Au) gate stack has an improved gate structure 124 overdrive performance, significantly increasing the gate 100 to 15.5V compared to the gate performance of a titanium nitride (TiN) based gate stack which can be 11V. These observations may demonstrate the promising potential of Scandium or Tantalum-based gate-stack in p-GaN HEMT 10.

In an experiment, a scandium or tantalum film with a targeted 100 nm thickness can be optimized on silicon (Si) or silicon dioxide (SiO2) substrates by electron beam evaporation initially. The scandium or tantalum source material (99.9% pure) can be taken in a graphite crucible and heated by an e-beam to optimize power percentages and time readings of ramps to melt the scandium or tantalum source material can be shown in the below table.

| RAMP-1 | | SOAK-1 | RAMP-2 | | SOAK-2 | Dep. |
|---|---|---|---|---|---|---|
| Power | Time | Time | Power | Time | Time | Power |
| (%) | (min) | (min) | (%) | (min) | (min) | (%) |
| 17 | 12 | 2 | 36 | 13 | 4 | 40 |

In the next step, the deposition for the targeted 100 nm began on a Si/SiO2 substrate that can be kept at room temperature. The work pressure was 4E-6 Torr. The deposition rate can be monitored by a deposition controller and the film thickness can be monitored by a quartz crystal unit. The deposition rate can be held at 0.1 nm/sec. The resistivity of the deposited film can be 4.4E-6 to 4.7E-6 ohm-cm when measured using a four-point method.

The HEMT device 10 used for this study may be fabricated on a commercial grade 600V E-mode GaN-on-Si wafer as shown in FIGS. 1A to 1B and the fabrication process flow given in FIG. 1C where a multi-layer gate metal stack of scandium (Sc) or tantalum (Ta), nickel (Ni), gold (Au), a silicon dioxide (SiOx) may be deposited using electron beam evaporation at room temperature. The silicon dioxide (SiOx) may be used as a hard mask to ensure a self-aligned p-GaN etching p-process.

The next step may be followed by MESA isolation, source/drain ohmic contact formation, and finally SiOₓ passivation. The SiOₓ may be etched in the source, drain, and gate pad regions. The next step may be followed by metal thickening with nickel (Ni)/aluminium (Al)/nickel (Ni)/gold (Au) stack and a low temperature of 250° C. annealing for one hour.

Furthermore, a computational analysis using a Centaurus Technology Computer-Aided Design (TCAD) may be performed to gain physical insights into the experimental findings. For comparison, titanium nitride (TN) gate-stack High Electron Mobility Transistor (HEMT) may also be simultaneously fabricated. More than 50 transistors per process may be analysed to determine the performance of the proposed gate structure 124.

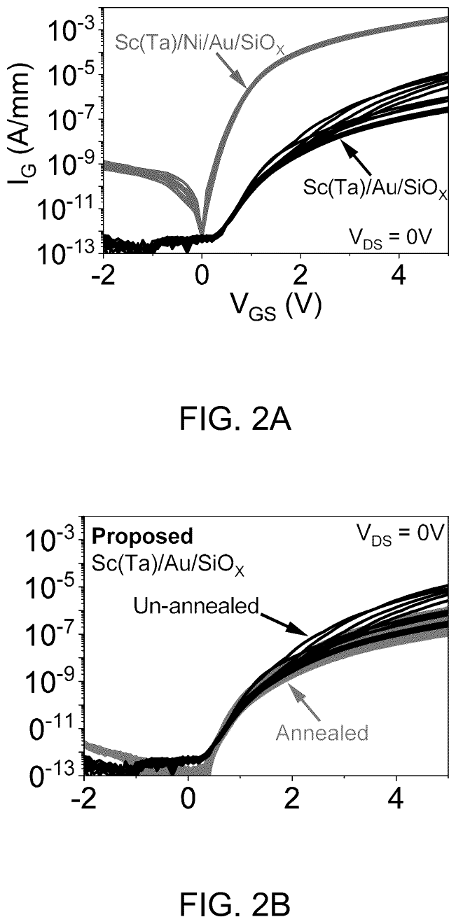

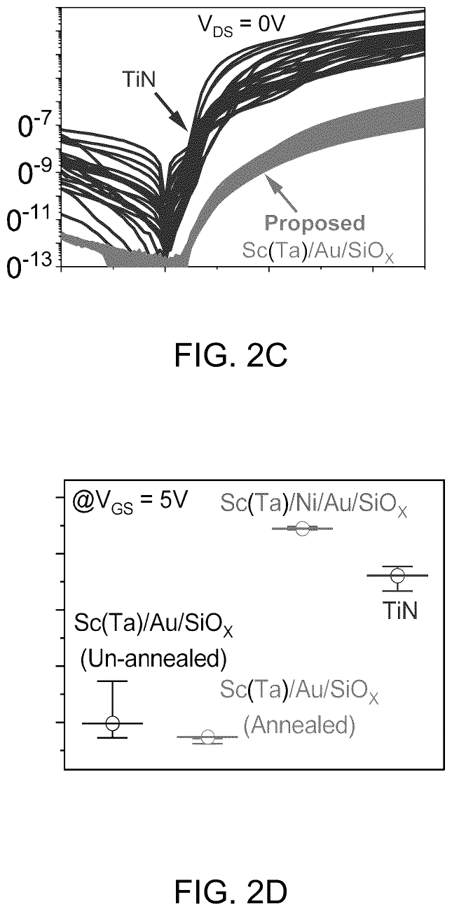

Referring to FIG. 2A, in an embodiment, the combination of scandium (Sc) or tantalum (Ta) metal and gold or a combination of scandium or tantalum metal and gold (Au) metal with silicon dioxide may produce a lower leakage current compared to the combination of Sc or Ta/Ni/Au/SiOx.

Referring to FIG. 2B, in an embodiment, the annealing process implemented with the combination of scandium (Sc) or tantalum (Ta) metal and gold or a combination of scandium or tantalum metal and gold (Au) metal with silicon dioxide may produce a lower leakage current compared to the unannealed combination of Sc or Ta/Au/SiOx.

Referring to FIG. 2C illustrates a comparison of the improvement in metal/p-GaN Schottky contact with the widely adopted TiN-based gate stack, showing considerably lower leakage for the Sc/A u or Ta/A u gate stack which can further compare the gate leakage and variability of these three gate metal stacks, which may indicate suppressed leakage and variability for the Sc/Au or Ta/Au stack. The improved variability may suggest an improved Sc/p-GaN interface.

Referring to FIG. 2D, in an embodiment, leakage current variation may be seen with gate stack variation. Annealed combination of the gate stack with Sc or Ta/Au/SiOx may produce a lower leakage current compared to the gate stack combination of Sc or Ta/Ni/Au/SiOx, and the unannealed gate stack combination of Sc or Ta/Au/SiOx.

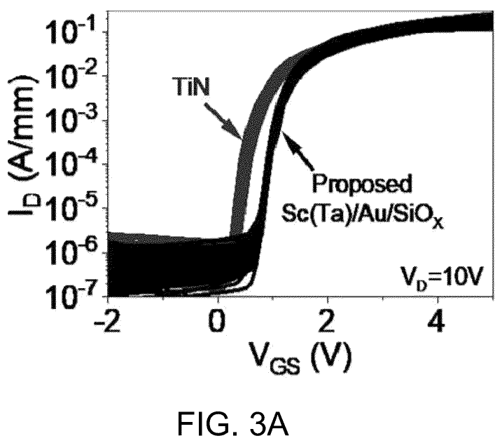

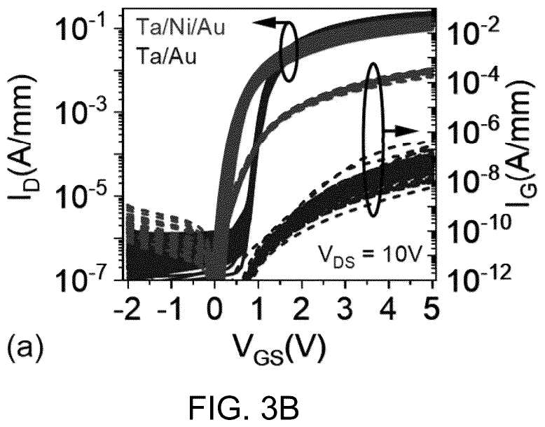

Referring to FIG. 3A, the transfer characteristics (drain current (ID)-versus gate-source voltage (VGS) of p-GaN HEMT 10 with gate metal stacks based on Sc/Au or Ta/Au and TiN are disclosed. The gate stack may exhibit similar ON/OFF ratios, with the Sc/Au or Ta/Au stack showing a increased threshold voltage (VTh) of 400 mV approx. and reduced variability.

The stability of gate stacks can be compared under similar voltage stress conditions for 500 seconds with TiN. The stability of gate stacks can be compared under similar voltage stress conditions for 500 seconds with Sc/Au. Further, the drain current may improve with the gate stack combination of Sc or Ta/Au/SiOx compared to the gate stack combination of Sc or Ta/Ni/Au/SiOx.

Referring to FIG. 3B, a graphical representation comparing the threshold voltage (VTH) drifts with HEM Ts employing proposed gate-based on Sc/Au or Ta/Au with and without Ni is disclosed.

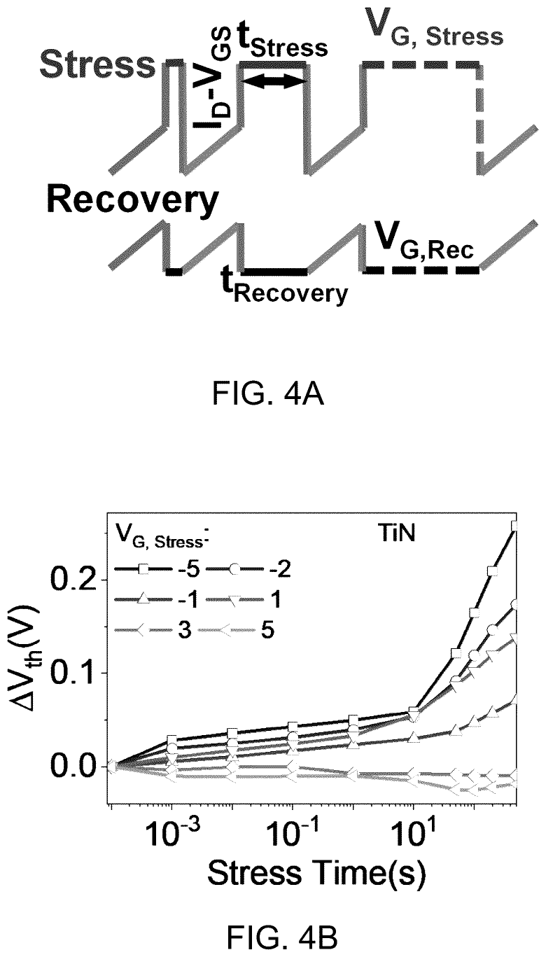

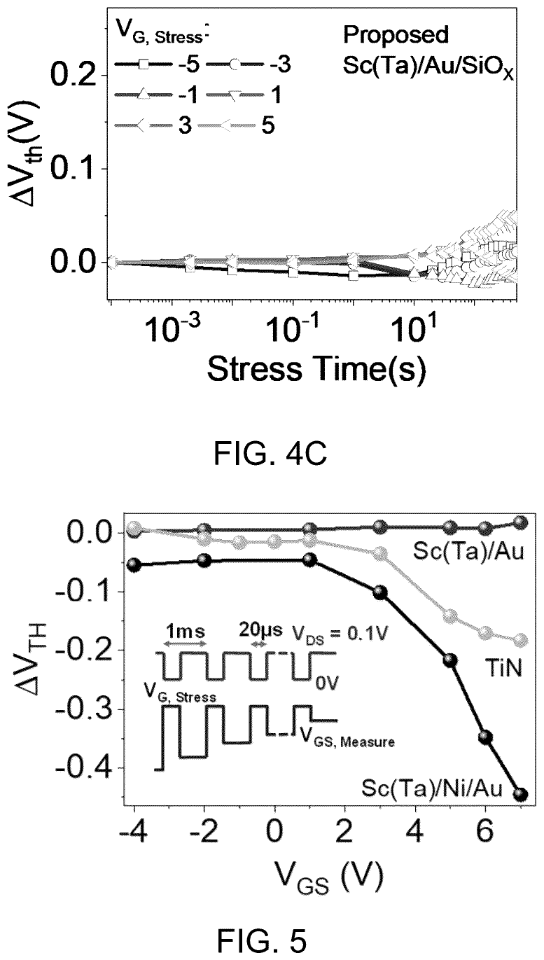

As illustrated in FIG. 4A, in an embodiment, stress may be applied intermittently to the proposed gate to determine one or more performance characteristics with the gate.

As illustrated in FIG. 4B-4C, in an embodiment, the TiN-based gate stack may include a higher variation in the threshold voltage compared to the proposed gate during the stress test over long period stress conditions.

As illustrated in FIG. 5, the threshold voltage for proposed gate with Sc/Au or Ta/Au remains stable under pulse stress conditionscompared to the TiN based gate, and the gate Sc/Au or Ta/Au and TiN.

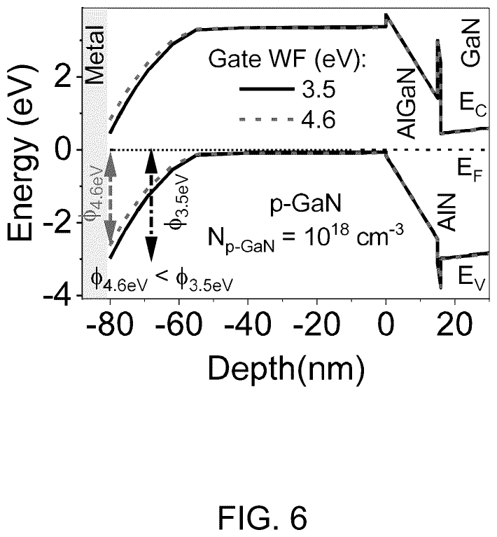

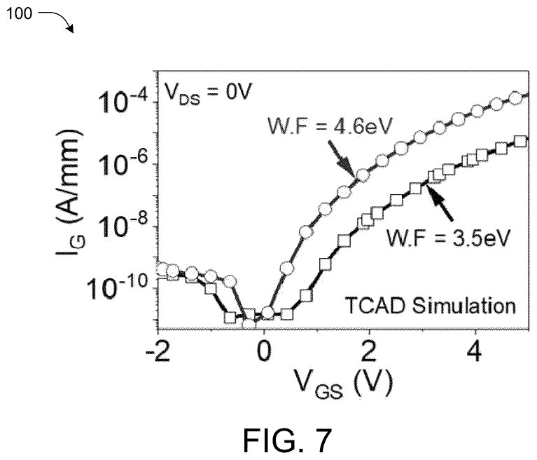

As illustrated in FIG. 6, a graphical representation of an energy band diagram of the proposed gate (Sc˜3.5 eV, Ta˜4.2 eV) metal stacking as compared to conventional (TiN˜4.6 eV) gate stack with the p-GaN structure is disclosed. Referring to FIG. 7, the comparison of forward gate leakage with gate breakdown can be disclosed such that the result may reveal the proposed gate of the Sc/Au or Ta/Au-based gate metal stack as the layer 104 can mitigate the existing problem of gate leakage for p-GaN gate HEMTs.

Referring to FIG. 7, a graphical representation of the TCAD based gate leakage characteristics of ultra-low work function (Sc˜3.5 eV, Ta˜4.2 eV) metal stacking of the proposed gate as compared to conventional (TiN˜4.6 eV) gate stack.

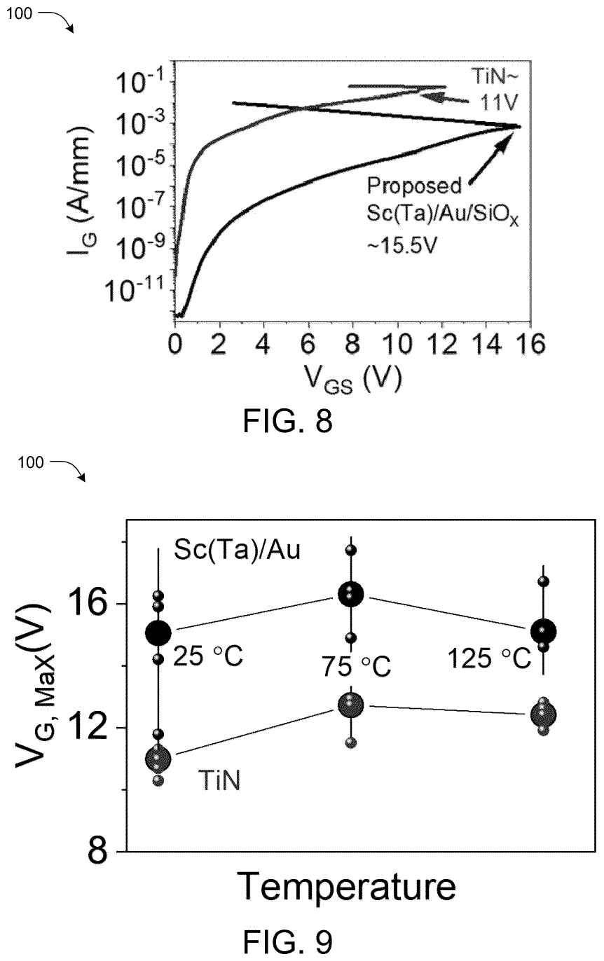

As illustrated in FIG. 8, in an embodiment, the proposed gate results in a breakdown voltage of 15.5V compared to the TiN based gate with a threshold voltage of 11V.

As illustrated in FIG. 9, in an embodiment, the temperature variation of gate breakdown voltage of the TiN based gate compared to the proposed gate is illustrated.

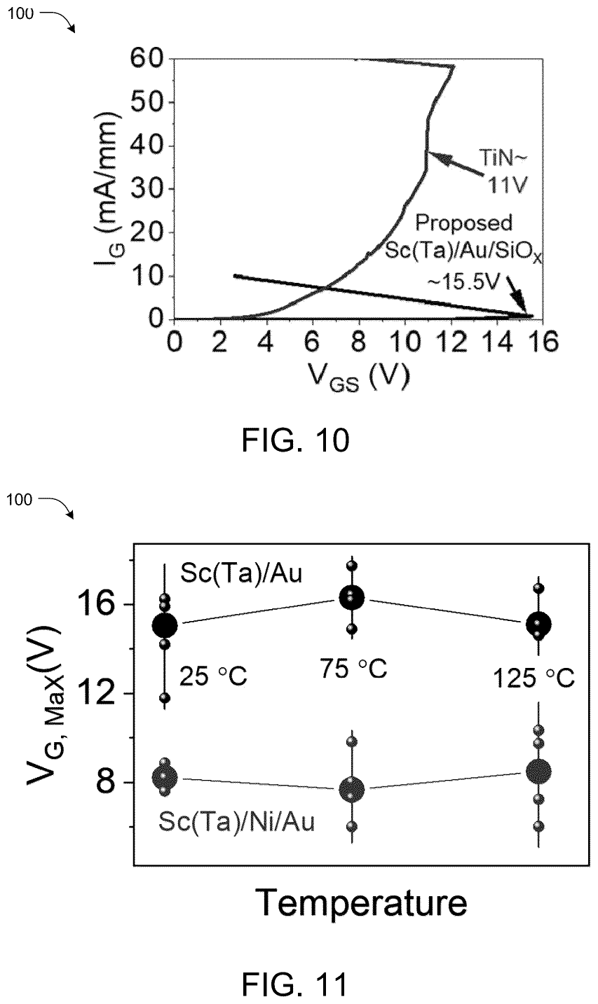

As illustrated in FIG. 10, in an embodiment, the variation of breakdown voltage, between the proposed gate and the TiN based gate is illustrated.

As illustrated in FIG. 11, temperature variation of the proposed gate with the Sc/Au or Ta/Au with and without Ni is illustrated.

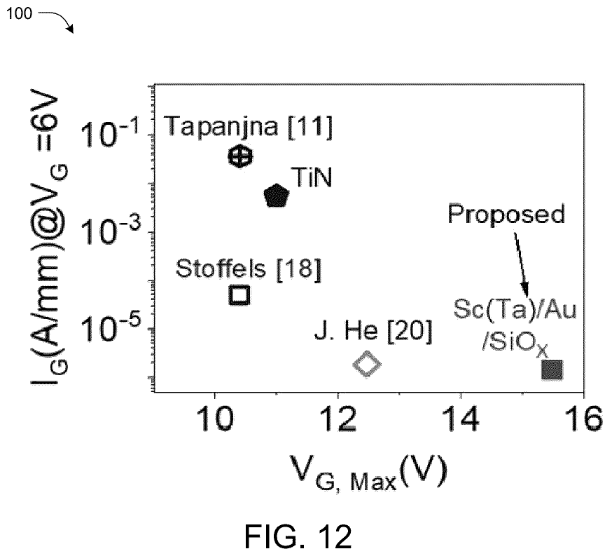

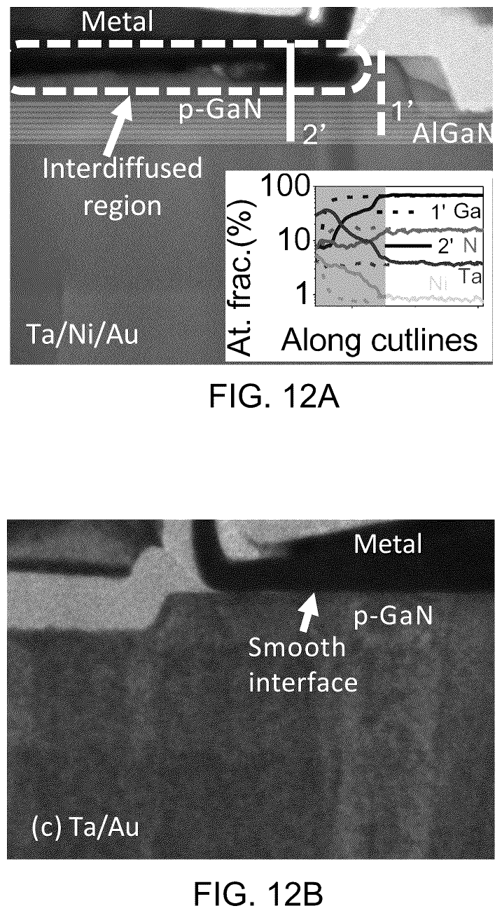

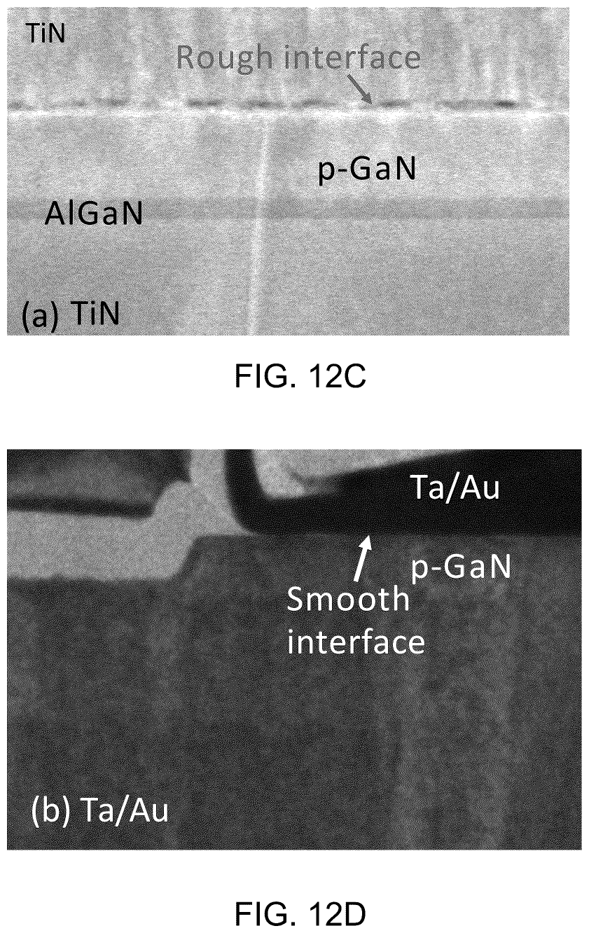

As illustrated in FIG. 12, in an embodiment, variation in breakdown voltage and gate leakage of the proposed gate with start of the art solutions may be observed.

As illustrated in FIGS. 12A-12D, Transmission electron microscopy schematic representations of the proposed gate are disclosed.

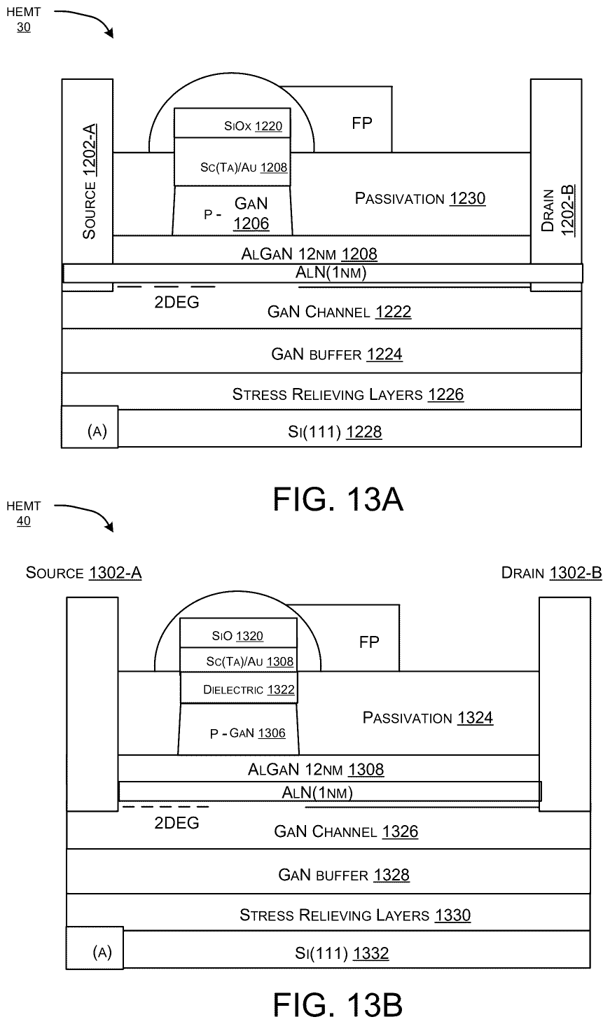

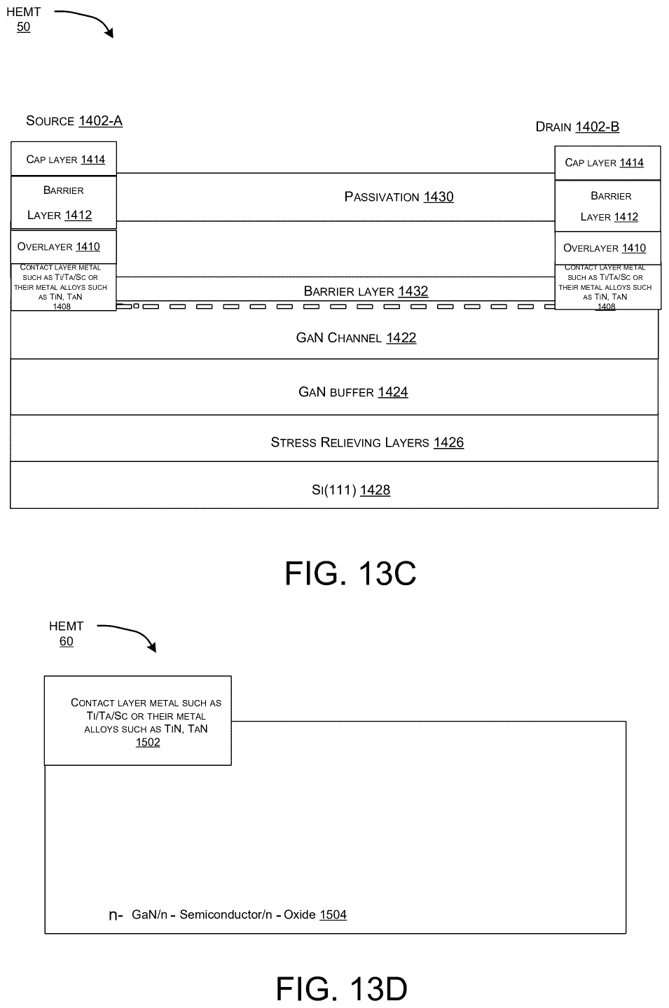

As illustrated in FIG. 13A in an embodiment, the High Electron Mobility Transistor (HEMT) device 30 may include a gate structure land a source drain structure (1202-A, 1202-B) where the gate structure may include a p-type capping layer 1206, and a first layer 1208 configured with the p-type capping layer 1206 to form a Schottky contact with the p-type capping layer 1206. The p-type capping layer 1206 may be disposed on a barrier layer 1208, and the barrier layer 1208 may be configured with a heterojunction structure formed with any or a combination of Aluminium and Gallium Nitride (AlGaN), Aluminium Nitride (AlN), Indium Nitride (InN), and their corresponding alloys. The p-type capping layer 1206 may be formed with any or a combination of p-type Aluminum Titanium Oxide (p-AlTiO), p-type Nickel Oxide (p-NiOx), a p-type Gallium Nitride (p-GaN) in a crystalline form or an amorphous form.

In an embodiment, the first layer 1208 may include any or the combination of the scandium (Sc) or the tantalum (Ta) metal with or without gold (Au) to make the Schottky contact with the p-type capping layer 1206 in order to suppress gate leakage, improve gate breakdown, and stability to prevent leakage of electric current from the gate structure to the heterojunction structure.

In an embodiment, a layer 1220 with any or a combination of Silicon Dioxide (SiO₂), Silicon Nitride (SiN), and Aluminium Oxide (AlOx) may be disposed on the first layer 1208, acting as a hard mask for removal of the first layer 1208 among non-gated regions.

In an embodiment, the heterojunction structure may include a GaN channel 1222, a GaN buffer 1224, one or more stress relieving layers 1226, and a substrate 1228. Further, a passivation layer 1230 may be configured between the source structure 1202-A and the drain structure 1202-B.

As illustrated in FIG. 13B in an embodiment, the High Electron Mobility Transistor (HEMT) device 40 may include a gate structure and a source drain structure (1302-A, 1302-B) where the gate structure may include a p-type capping layer 1306, and a first layer 1308 configured with the p-type capping layer 1306 and separated by a dielectric layer (1322) to prevent leakage flow from gate metal to the p-type capping layer 1306. The p-type capping layer 1306 may be disposed on a barrier layer 1308, and the barrier layer 1308 may be configured with a heterojunction structure formed with any or a combination of Aluminium and Gallium Nitride (AlGaN), Aluminium Nitride (AlN), Indium Nitride (InN), and their corresponding alloys. The p-type capping layer 1306 may be formed with any or a combination of p-type Aluminum Titanium Oxide (p-AlTiO), p-type Nickel Oxide (p-NiOx), a p-type Gallium Nitride (p-GaN) in a crystalline form or an amorphous form.

In an embodiment, the first layer 1308 may include any or the combination of the scandium (Sc) or the tantalum (Ta) metal with or without gold (Au) to make the Schottky contact with the p-type capping layer 1306 in order to suppress gate leakage, improve gate breakdown, and stability to prevent leakage of electric current from the gate structure to the heterojunction structure.

In an embodiment, a layer 1320 with any or a combination of Silicon Dioxide (SiO₂), Silicon Nitride (SiN), and Aluminium Oxide (AlOx) may be disposed on the first layer 1308, acting as a hard mask for removal of the first layer 1308 among non-gated regions.

In an embodiment, a dielectric medium 1322 such as SiOx, SiNx, Al₂O₃, or any or a combination of semiconductors comprising AlN, GaON, GaOx may separate the scandium (Sc) or the tantalum (Ta) metal and the p-GaN structure.

In an embodiment, a dielectric medium such as SiOx, SiNx, Al₂O₃, or any or a combination of semiconductors comprising AlN, GaON, GaOx may separate the scandium (Sc) or the tantalum (Ta) metal and the p-GaN structure. The heterojunction structure may include a GaN channel 1326, a GaN buffer 1328, one or more stress relieving layers 1330, and a substrate 1332. Further, a passivation layer 1324 may be configured between the source structure 1302-A and the drain structure 1302-B.

As illustrated in FIG. 13C in an embodiment, a High Electron Mobility Transistor (HEMT) device 50 may include a gate structure and a source drain structure (1402-A, 1402-B). The source drain structure (1402-A, 1402-B) may include a multilayer stack with any or a combination of a contact layer, an overlayer, a barrier contact layer, and a cap layer, and the contact layer may make ohmic contact with a heterojunction structure 1416. The contact layer 1408 may include any or a combination of a low work function metal or metal alloy such as scandium (Sc) or the tantalum (Ta) or Titanium metal or Titanium Nitride (TiN) or Tantalum Nitride (TaN), with or without Silicon (Si) doping to form the ohmic contact with the heterojunction structure.

Further, a passivation layer 1418 and a barrier layer 1420 may be configured between the source structure 1402-A and the drain structure 1402-B. the contact layer may include any or a combination of scandium (Sc) or the tantalum (Ta) metal with or without Silicon (Si) doping to form the ohmic contact with a heterojunction structure. The heterojunction structure 1416 may include the (a GaN channel 1422 a GaN buffer 1424, one or more stress relieving layers 1426, and a substrate 1428. Further, a passivation layer 1430 and a barrier layer 1432 may be configured between the source structure 1402-A and the drain structure 1402-B. As illustrated in FIG. 13D, in an embodiment, a HEMT device 60 may include a contact layer 1502 with any or a combination of a low work function metal or metal alloy such as scandium (Sc) or the tantalum (Ta) or Titanium metal or Titanium Nitride (TiN) or Tantalum Nitride (TaN), with or without Silicon (Si) doping to form the ohmic contact with the heterojunction structure with a p-GaN/p-Semiconductor/p-dielectric structure/n Oxide layer 1504.

While considerable emphasis has been placed herein on the particular features of this disclosure, it will be appreciated that various modifications can be made and that many changes can be made in the preferred embodiments without departing from the principles of the disclosure. These and other modifications in the nature of the disclosure or the preferred embodiments will be apparent to those skilled in the art from the disclosure herein, whereby it is to be distinctly understood that the foregoing descriptive matter is to be interpreted merely as illustrative of the disclosure and not as a limitation.

The embodiments herein and the various features and advantageous details thereof are explained with reference to the non-limiting embodiments in the description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

The use of the expression “at least” or “at least one” suggests the use of one or more elements or ingredients or quantities, as the use may be in the embodiment of the disclosure to achieve one or more of the desired objects or results.

Any discussion of documents, acts, materials, devices, articles and the like that has been included in this specification is solely for the purpose of providing a context for the disclosure. It is not to be taken as an admission that any or all of these matters form a part of the prior art base or were common general knowledge in the field relevant to the disclosure as it existed anywhere before the priority date of this application.

The numerical values mentioned for the various physical parameters, dimensions or quantities are only approximations and it is envisaged that the values higher/lower than the numerical values assigned to the parameters, dimensions or quantities fall within the scope of the disclosure, unless there is a statement in the specification specific to the contrary.

### ADVANTAGES OF THE INVENTION

The present disclosure provides a gate structure that reduces the leakage current in a high electron mobility transistor (HEMT).

The present disclosure provides a gate structure that produces a stable threshold voltage over a period.

The present disclosure provides a gate structure with the combination of the scandium (Sc) or tantalum (Ta) metal and gold or the combination of scandium or tantalum metal and gold (Au) metal that generates an ultra-low work function up to 3.5 eV for Sc and up to 4.2 eV for Ta.

The present disclosure provides a gate structure where the combination of the scandium (Sc) or tantalum (Ta) metal and gold or the combination of scandium or tantalum metal and gold (Au) metal generates a breakdown voltage up to 15.5V.

The present disclosure provides a gate structure where the combination of the scandium (Sc) or tantalum (Ta) metal and gold or the combination of scandium or tantalum metal and gold (Au) metal suppresses gate leakage by around 4˜order of magnitude as compared to conventional gate stacks.

The present disclosure provides a gate structure where the combination of the scandium (Sc) or tantalum (Ta) metal and gold or the combination of scandium or tantalum metal and gold (Au) metal improves gate threshold voltage stability under pulse stress and long term stress conditions.

The present disclosure provides a gate structure where the combination of the scandium (Sc) or tantalum (Ta) metal is capable to form an ohmic contact with the n-GaN, n-Oxide, 2DEG of the heterojunction structure due to the ultra-low work function of the proposed metal stacks

I/we claim:

1. A High Electron Mobility Transistor (HEM T) device (10) comprising:
a gate structure (124) and a source drain structure (102-A, 102-B), wherein the gate structure (124) comprises a p-type capping layer (108), and a first layer (104) configured with the p-type capping layer (108) to form a Schottky contact with the p-type capping layer (108), and wherein the source drain structure (102-A, 102-B) comprises a multilayer stack with any or a combination of a contact layer (124-1), an overlayer (124-2), a barrier contact layer (124-3), and a cap layer (124-4), and wherein the contact layer (124-1) makes ohmic contact with a heterojunction structure.

2. The HEMT device (10) as claimed in claim 1, wherein the first layer (104) comprises any or the combination of a low work function (<4.6 eV) metal or metal alloy such as scandium (Sc˜3.5 eV), the tantalum (Ta˜4.2 eV), Ti (˜4.33 eV), Titanium Nitride (TiN) or Tantalum Nitride (TaN), with or without gold (Au) to make the Schottky contact with the p-type capping layer (108) in order to suppress gate leakage, improve gate breakdown, and stability to prevent leakage of electric current from the gate structure (124) to the heterojunction structure.

3. The HEMT device (10) as claimed in claim 1, wherein the contact layer (124-1) comprises any or a combination of a low work function metal or metal alloy such as scandium (Sc) or the tantalum (Ta) or Titanium metal or Titanium Nitride (TiN) or Tantalum Nitride (TaN), with or without Silicon (Si) doping to form the ohmic contact with the heterojunction structure.

4. The HEMT device (10) as claimed in claim 1, wherein the p-type capping layer (106) is disposed on a barrier layer, and wherein the barrier layer is configured with the heterojunction structure formed with any or a combination of Aluminium and Gallium Nitride (AlGaN), Aluminium Nitride (AiN), Indium Nitride (InN), and their corresponding alloys.

5. The HEMT device (10) as claimed in claim 1, wherein the p-type capping layer (108) is formed with any or a combination of p-type Aluminum Titanium Oxide (p-AlTiO), p-type Nickel Oxide (p-NiOx), a p-type Gallium Nitride (p-GaN) in a crystalline form or an amorphous form.

6. The HEMT device (10) as claimed in claim 1, wherein a layer (104) with any or a combination of Silicon Dioxide (SiO₂), Silicon Nitride (SiN), and Aluminium Oxide (AlOx) is disposed on the first layer (106), acting as a hard mask for removal of the first layer (106) among non-gated regions.

7. A semiconductor device (20), comprising any or a combination of a low work function metal or metal alloy such as scandium (Sc) or the tantalum (Ta) or Titanium metal or Titanium Nitride (TiN) or Tantalum Nitride (TaN), to form a Schottky contact with the p-capping layer and make an ohmic contact with a n-GaN/n-Semiconductor/n-dielectric layer or a Schottky contact with a p-GaN/p-Semiconductor/p-dielectric structure.

8. The HEMT device (10) as claimed in claim 1, wherein a dielectric medium such as SiOx, SiNx, Al₂O₃, or any or a combination of semiconductors comprising AlN, GaON, GaOx separates the low work function metal or metal alloy such as scandium (Sc) or the tantalum (Ta) or Titanium metal or Titanium Nitride (TiN) or Tantalum Nitride (TaN), and the p-capping layer in the gate structure.

9. A method (200) for fabricating a HEMT device (10), comprising:
depositing (202), a gate structure with any or combination of a low work function metal or metal alloy such as scandium (Sc) or the tantalum (Ta) or Titanium metal or Titanium Nitride (TiN) or Tantalum Nitride (TaN), and a hard mask with any or combination of a SiOx layer, SiNx layer, an AlOx layer, an AlN layer, a Cr layer, an Au layer, and a Ni layer;
etching (204), a p-GaN layer with the gate structure;
etching (206), a MESA layer with the gate structure for isolation of a HEMT device (10);
forming (208), an ohmic contact with a source and drain structure of the HEMT device (20) using a metal stack;
depositing (210), for passivation using any or a combination of a SiOx layer, a SiNx layer, an AlOx layer, a TiOx layer, and an AlN layer, in a single layer or a multilayer stacking of any stoichiometry or stress;
performing (212), passivation opening and metal thickening of the gate structure; and
performing (214), post metallization annealing of the gate structure.

10. The method (200) as claimed in claim 9, wherein the method comprises depositing a first layer (106) with any or the combination of the scandium (Sc) or the tantalum (Ta) metal with or without gold (Au) to make the Schottky contact with the p-type capping layer (104) to suppress gate leakage, improve gate breakdown, and stability to prevent leakage of electric current from the gate structure to a heterojunction structure configured with the HEMT device (10).

11. The method (200) as claimed in claim 9, the method (200) comprising:
disposing, the p-type capping layer (108) on a barrier layer (110), wherein the barrier layer (110) is configured with the heterojunction structure formed of any or a combination of Aluminium and Gallium Nitride (AlGaN), Aluminium Nitride (AlN), Indium Nitride (InN), and their corresponding alloys; and
disposing, a layer (104) with any or a combination of Silicon Dioxide (SiO₂), Silicon Nitride (SiN), and Aluminium Oxide (AlOx) on the first layer (106), acting as a hard mask for removal of the first layer (106) among non-gated regions.
